(19) United States
(12) Patent Application Publication
(10) Pub. No.: US 2026/0107856 A1
(43) Pub. Date: Apr. 16, 2026

(54) SEMICONDUCTOR PACKAGES AND METHODS OF FORMING THE SAME

(71) Applicant: Taiwan Semiconductor Manufacturing Company, Ltd., Hsinchu (TW)

(72) Inventors: Hung-Min Chang, Hsinchu City (TW); Chien-Chang Lin, New Taipei City (TW); Hsuan-Cheng Kuo, Hsinchu County (TW); Shih-Hui Wang, New Taipei City (TW); Tzu-Shiun Sheu, Hsinchu (TW)

(73) Assignee: Taiwan Semiconductor Manufacturing Company, Ltd., Hsinchu (TW)

(21) Appl. No.: 19/046,429

(22) Filed: Feb. 5, 2025

Related U.S. Application Data
(60) Provisional application No. 63/706,729, filed on Oct. 13, 2024.

(51) Int. Cl. H01L 21/50; H01L 23/00; H01L 23/10; H01L 23/367; H01L 23/538; H01L 25/18

(52) U.S. Cl. CPC H10W 95/00; H10W 40/22; H10W 42/121; H10W 76/60; H10W 90/00; H10W 70/611; H10W 72/30; H10W 90/401

(57) ABSTRACT

A semiconductor package includes a board substrate, an integrated circuit component and a ring structure. The integrated circuit component is bonded to the board substrate and includes at least one semiconductor die. The ring structure is disposed on the board substrate and encircles the integrated circuit component, wherein the ring structure includes a plurality of cavities around a boundary of the integrated circuit component.

### CROSS-REFERENCE TO RELATED APPLICATION

This application claims the priority benefit of U.S. provisional application Ser. No. 63/706,729, filed on Oct. 13, 2024. The entirety of the above-mentioned patent application is hereby incorporated by reference herein and made a part of this specification.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing semiconductor packages have been generally adequate for their intended purposes, they have not been entirely satisfactory in all respects.

### BRIEF DESCRIPTION OF THE DRAWINGS

FIG. 1 is a simplified local top view of a semiconductor package in accordance with some embodiments.

FIG. 2A, FIG. 2B and FIG. 2C are schematic cross-sectional views of a semiconductor package taken along the lines A-A′, B-B′ and C-C′ of FIG. 1, respectively.

FIG. 3 is a simplified local top view of a semiconductor package in accordance with some embodiments.

FIG. 4A, FIG. 4B and FIG. 4C are schematic cross-sectional views of a semiconductor package taken along the lines A-A′, B-B′ and C-C′ of FIG. 3, respectively.

FIG. 5 is a simplified local top view of a semiconductor package in accordance with some embodiments.

FIG. 6A, FIG. 6B and FIG. 6C are schematic cross-sectional views of a semiconductor package taken along the lines A-A′, B-B′ and C-C′ of FIG. 5, respectively.

FIG. 7 is a simplified local top view of a semiconductor package in accordance with some embodiments.

FIG. 8A, FIG. 8B and FIG. 8C are schematic cross-sectional views of a semiconductor package taken along the lines A-A′, B-B′ and C-C′ of FIG. 7, respectively.

FIG. 9 is a simplified local top view of a semiconductor package in accordance with some embodiments.

FIG. 10A and FIG. 10B are schematic cross-sectional views of semiconductor packages taken along the line A-A′ of FIG. 9, respectively.

FIG. 11 is a simplified local top view of a semiconductor package in accordance with some embodiments.

FIG. 12A and FIG. 12B are schematic cross-sectional views of semiconductor packages taken along the line A-A′ of FIG. 11, respectively.

FIG. 13 to FIG. 21 are simplified local top views of semiconductor packages in accordance with some embodiments.

FIG. 22 illustrates a process flow of forming a semiconductor package in accordance with some embodiments.

### DETAILED DESCRIPTION

The following disclosure provides many different embodiments, or examples, for implementing different features of the provided subject matter. Specific examples of components and arrangements are described below for the purposes of conveying the present disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same reference numerals and/or letters may be used to refer to the same or similar parts in the various examples the present disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose semiconductor packages and forming methods thereof. In a semiconductor package of the disclosure, a ring structure with cavities is mounted on a board substrate and surrounds an integrated circuit component, so as to reduce the ring stiffness and therefore mitigate the bending force from the expansion of the ring structure and the overlying lid to the board substrate during the high-temperature (HT) process.

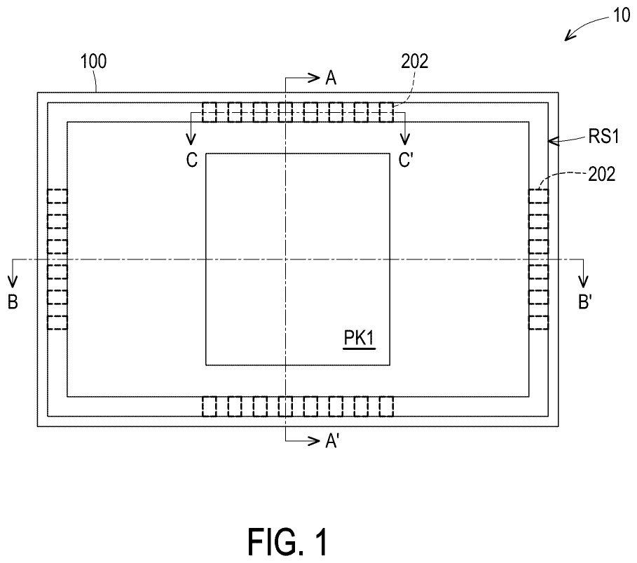

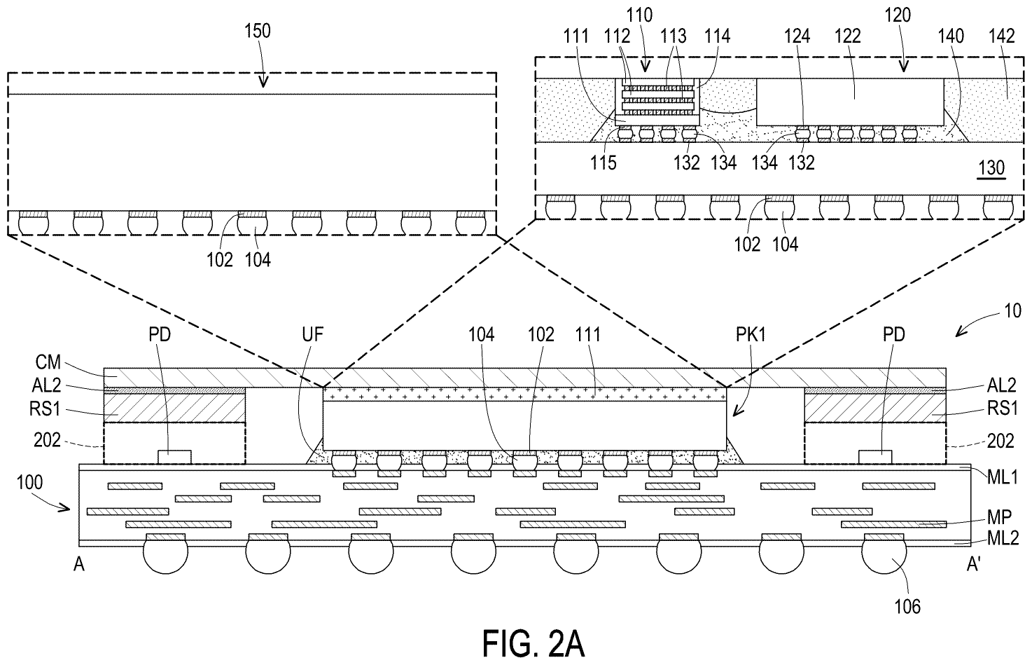

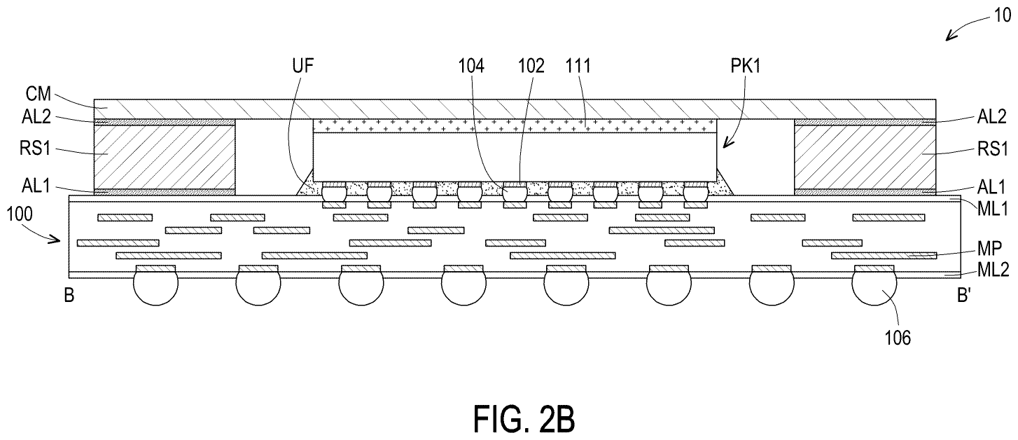

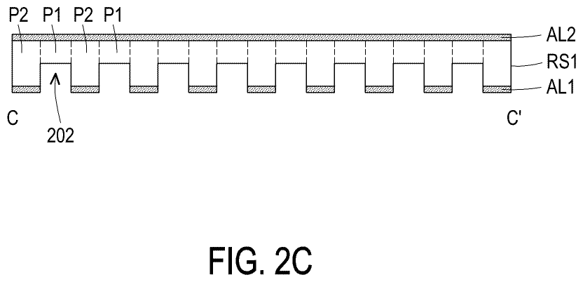

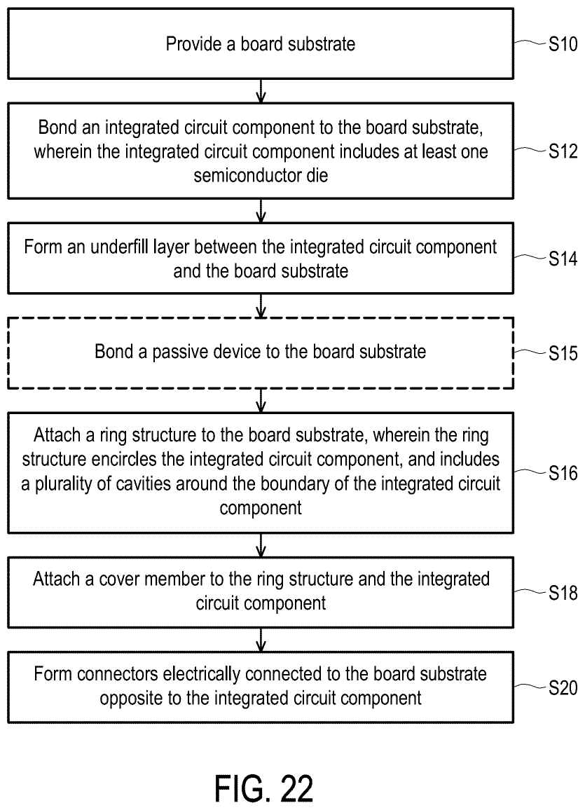

FIG. 1 is a simplified local top view of a semiconductor package in accordance with some embodiments. For clarity and illustration purposes, only few components such as an integrated circuit component, a ring structure and a board substrate are shown in FIG. 1. Through the specification, cavities denoted by a dotted line indicate that the cavities are located in the lower part of the ring structure. In some embodiments, FIG. 2A, FIG. 2B and FIG. 2C are schematic cross-sectional views of a semiconductor package taken along the lines A-A′, B-B′ and C-C′ of FIG. 1, respectively. The corresponding processes are also reflected schematically in the process flow shown in FIG. 22.

Referring to FIG. 1, FIG. 2A and FIG. 2B, a board substrate 100 is provided. The respective process is shown as process S10 in the process flow as shown in FIG. 22. In some embodiments, the board substrate 100 includes a core layer and two build-up layers on opposite sides of the core layer. In some embodiments, the board substrate 100 includes wiring patterns MP that penetrate through the core layer and the build-up layers for providing electrical routing between different devices and/or electric components. The wiring patterns MP include metal lines, metal vias, metal pads and/or metal connectors. The board substrate 100 is referred to as a “printed circuit board (PCB)” in some examples. In other embodiments, the core layer of the board substrate 100 may be omitted as needed, and such board substrate 100 is referred to as a “coreless board substrate”.

In some embodiments, mask layers ML1 and ML2 are further disposed on the opposite sides of the board substrate 100. The mask layers ML1 and ML2 may be formed of a material having a chemical composition of silica, barium sulfate and epoxy resin, and/or the like. For example, the mask layers ML1 and ML2 may serve as solder masks and may be selected to prevent short, corrosion or contamination of the circuit patterns and protect the board substrate from external impacts and chemicals.

An integrated circuit component PK1 is disposed over and bonded to the board substrate 100. The respective process is shown as process S12 in the process flow as shown in FIG. 22. The integrated circuit component PK1 may be a single semiconductor die or a package structure including multiple semiconductor dies, as shown in local views of FIG. 2A.

In some embodiments, the integrated circuit component PK1 is a single semiconductor die 150. The semiconductor die 150 may be a logic die, a memory die, a CPU, a GPU, an xPU, a MEMS die, a SoC die, a photonic die or the like. In some embodiments, the semiconductor die 150 includes a semiconductor substrate and a device layer. The device layer may include a transistor such as a fin field effect transistor (FinFET), a nanostructure FET (nano-FET) (e.g., a nanosheet transistor, a nanowire transistor or a gate-all-around transistor), a planar FET, the like, or a combination thereof. The device layer further includes an interconnect structure electrically connected to the transistor, and a passivation layer covering the interconnect structure. In some embodiments, the semiconductor die 150 further includes metal pads 102 and metal connectors 104 for providing electrical connection between the semiconductor die 150 and the underlying board substrate 100. The metal pads 102 may include Al, Cu, Ti, Ta, W, Ru, Co, Ni, the like, or a combination thereof. The metal connectors 104 may include solder or the like.

In some embodiments, the integrated circuit component PK1 is a package structure including an interposer 130 and multiple semiconductor dies 110 and 120 disposed on and electrically connected to the interposer 130 through metal connectors 134.

In some embodiments, the interposer 130 includes a substrate, and through vias extending from one side to the opposite side of the substrate. In some embodiments, the substrate is a silicon substrate, and the interposer 130 is a silicon-containing interposer. In other embodiments, the substrate is a dielectric substrate or a glass substrate, and the interposer 130 is an organic interposer or a glass interposer. In some embodiments, the interposer 130 is an active interposer that contains at least one functional device or integrated circuit device on/in the substrate. Such active interposer is referred to as a “device-containing interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer 130 is a passive interposer, which is lack of a functional device or integrated circuit device. Such passive interposer is referred to as a “device-free interposer” in some examples. In some embodiments, the interposer 130 further includes metal pads 102 and metal connectors 104 for providing electrical connection between the interposer 130 and the underlying board substrate 100. The metal pads 102 may include Al, Cu, Ti, Ta, W, Ru, Co, Ni, the like, or a combination thereof. The metal connectors 104 may include solder or the like. The metal connectors 104 are referred to as “micro-bumps” in some examples. In some embodiments, the interposer 130 further includes metal pads 132 and metal connectors 134 for providing electrical connection between the interposer 130 and the overlying semiconductor dies 110 and 120. The metal pads 132 may include Al, Cu, Ti, Ta, W, Ru, Co, Ni, the like, or a combination thereof. The metal connectors 134 may include solder or the like. The metal connectors 104 are referred to as “controlled collapse chip connection (C4) bumps”in some examples.

The semiconductor dies 110 and 120 may have the same or different functions and/or dimensions. Each of the semiconductor dies 110 and 120 may be a logic die, a memory die, a CPU, a GPU, an xPU, a MEMS die, a SoC die, a photonic die or the like. The dimension may be a height, a width, a size, a top-view area or a combination thereof. In some embodiments, the semiconductor die 110 includes a base chip 111, and chips 112 stacked on the base chip 111. The chips 112 are electrically connected to each other and to the base chip 111 through bumps 113. The chips 111 and 112 may include semiconductor substrates having active and/or passive devices formed therein. An encapsulation layer 114 is disposed on the base chip 111 to laterally wrap the chips 112 and the bumps 113. The encapsulation layer 114 may include a molding compound, a polymeric material, such as polyimide, epoxy resin, acrylic resin, phenol resin, benzocyclobutene (BCB), polybenzoxazole (PBO), the like, or a combination thereof. In some embodiments, metal pads 115 are formed on the base chip 111 opposite to the stacked chips 112. The metal pads 115 provide electrical connection between the semiconductor die 110 and the underlying interposer 130. In some embodiments, the semiconductor die 120 may have an element configuration similar to that of the semiconductor die 150 described above. For example, the semiconductor die 120 includes a semiconductor substrate and a device layer, and further includes metal pads 124 electrically connected to the underlying interposer 130. However, the disclosure is not limited thereto. In other embodiments, the semiconductor die 120 may be a bare die. In some embodiments, additional dummy dies other than the semiconductor dies 110 and 120 may be included in the integrated circuit component PK1 as needed. The bare die or dummy dies are configured to balance the CTE mismatch of the semiconductor package and therefore improve the warpage profile of the resulting semiconductor package.

In some embodiments, an underfill layer 140 is disposed between the semiconductor dies 110, 120 and the interposer 130 and around the metal connectors 134. The underfill layer 140 may include a resin, such as an epoxy resin or the like, and may be formed using dispensing, injecting, and/or spraying process. In some embodiments, an encapsulation layer 150 is formed on the interposer 130 to laterally encapsulate the semiconductor dies 110, 120 and the underfill layer 140. The encapsulation layer 150 may include a molding compound, a polymeric material, such as polyimide, epoxy resin, acrylic resin, phenol resin, benzocyclobutene (BCB), polybenzoxazole (PBO), the like, or a combination thereof. In some embodiments, the method of forming the encapsulation layer 150 includes performing a molding process followed by a curing process. In some embodiments, the surface of the encapsulation layer 150 is flush with the surfaces of the semiconductor dies 110, 120.

Referring to FIG. 2A and FIG. 2B, an underfill layer UF is disposed between the integrated circuit component PK1 and the board substrate 100 and around the metal connectors 104. The respective process is shown as process S14 in the process flow as shown in FIG. 22. The underfill layer UF may include a resin, such as an epoxy resin or the like, and may be formed using dispensing, injecting, and/or spraying process.

Referring to FIG. 1, FIG. 2A, FIG. 2B and FIG. 2C, in some embodiments, a ring structure RS1 is attached to the board substrate 100, wherein the ring structure RS1 encircles the integrated circuit component PK1, and includes multiple cavities 202 around the boundary of the integrated circuit component PK1. In some embodiments, the cavities 202 are disposed corresponding to four sides of the integrated circuit component PK1. The respective process is shown as process S16 in the process flow as shown in FIG. 22.

In some embodiments, the ring structure RS1 is attached to the board substrate 100 by an adhesive layer AL1. The ring structure RS1 is configured to reduce warpage and improve the heat dissipation performance. The ring structure RS1 has a high thermal conductivity greater than about 100 W/m*K, for example, and may be formed using a metal, a metal alloy, or the like. For example, the ring structure RS1 may be selected from the group consisting of Al, Cu, Ni, Co, and the like. The ring structure RS1 may also be formed of a composite material selected from the group consisting of silicon carbide, aluminum nitride, graphite, and the like. The cavities 202 of the ring structure RS1 are patterned by metal machining, which involves techniques that shape raw metal pieces into finished products. Metal machining utilizes cutting processes (like CNC machines for laser cutting) but also includes processes like turning, drilling, milling, and extrusion. In some embodiments, the adhesive layer AL1 includes a tape or a suitable glue material.

In some embodiments, the cavities 202 do not penetrate through the ring structure RS1 in a thickness direction thereof. Specifically, portions of the lower part of the ring structure RS1 are removed to form the cavities 202, as shown in FIG. 2C. From another point of view, the ring structure RS1 is patterned to have first portions P1 and second portions P2 alternatively, and the second portions P2 are thicker than the first portions P1. The multiple first portions P1 are separated from one another, while the multiple second portions P2 are connected to each other. As shown in FIG. 2A, FIG. 2B and FIG. 2C, one of the cavities 202 is encompassed by one first portion P1 and two second portions P2, and the cavity 202 faces the underlying board substrate 100. In some embodiments, the adhesive layer AL1 is a discontinuous adhesive layer between the ring structure RS1 and the underlying board substrate 100, and the adhesive layer AL2 is a continuous adhesive layer between the ring structure RS1 and the overlying cover member CM.

In some embodiments, at least one semiconductor die PD is located between the ring structure RS1 and the board substrate 100 and inserted into of at least one of the cavities 202 of the ring structure RS1, as shown in FIG. 2A. The semiconductor die PD may be attached to the board substrate 100, before the ring structure RS1 is attached to the board substrate 100, through soldering or a suitable method, with an additional underfill layer formed between the semiconductor die PD and the board substrate 100. The respective process is shown as process S15 in the process flow as shown in FIG. 22. In some embodiments, the semiconductor dies PD are passive devices (e.g., capacitors, resistors, inductors, varactors, and/or similar components) mounted on the board substrate 100, for instance, using surface mount technology (SMT) connection. The process S15 is optional and may be omitted as needed.

Referring to FIG. 2B and FIG. 2C, a lid or a cover member CM is attached to the ring structure RS1 and the integrated circuit component PK1 by an adhesive layer AL2. The respective process is shown as process S18 in the process flow as shown in FIG. 22. The cover member CM is configured to further reduce warpage and improve the heat dissipation performance. The cover member CM has a high thermal conductivity greater than about 100 W/m*K, for example, and may be formed using a metal, a metal alloy, or the like. For example, the cover member CM may be selected from the group consisting of Al, Cu, Ni, Co, and the like. The cover member CM may also be formed of a composite material selected from the group consisting of silicon carbide, aluminum nitride, graphite, and the like. The materials of the ring structure RS1 and the cover member CM may be the same or different. In some embodiments, the adhesive layer AL2 includes a tape or a suitable glue material.

In some embodiments, a thermal interface material (TIM) 111 is disposed between the ring structure RS1 and the integrated circuit component PK1. The thermal interface material 111 has a good thermal conductivity, which may be greater than about 2 W/m*K, and may be as equal to, or higher than, about 10 W/m*K or 50 W/m*K. In some embodiments, the thermal interface material 111 may include a polymer, resin, or epoxy as a base material, and a filler to improve its thermal conductivity. The filler may include a dielectric filler such as aluminum oxide, magnesium oxide, aluminum nitride, boron nitride, and diamond powder. The filler may also be a metal filler such as silver, copper, aluminum, or the like. The thermal interface material 111 has a thermal conductivity higher than the thermal conductivity of the adhesive layer AL2.

Referring to FIG. 2A and FIG. 2B, connectors 106 are formed below and electrically connected to the board substrate 100 opposite to the integrated circuit component PK1. The connectors 106 are electrically to the wiring patterns MP of the board substrate 100. In some embodiments, the connectors 106 may include solder bumps, and/or may include metal pillars (e.g., copper pillars), solder caps formed on metal pillars, and/or the like. The connectors 106 are referred to as “ball grid array (BGA) balls” in some examples. A semiconductor package 10 of the disclosure is thus completed.

In the semiconductor package 10 of the disclosure, a ring structure RS1 with cavities 202 is mounted on a board substrate 100 and surrounds an integrated circuit component PK1, so as to reduce the ring stiffness and therefore mitigate the bending force from the expansion of the ring structure and the overlying lid to the board substrate during the high-temperature (HT) process.

The above embodiments of FIG. 1, FIG. 2A, FIG. 2B and FIG. 2C in which the cavities 202 are disposed in the lower part of the ring structure RS1 are provided for illustration purposes, and are not construed as limiting the present disclosure. In other embodiments, the cavities may be disposed in the upper part of the ring structure.

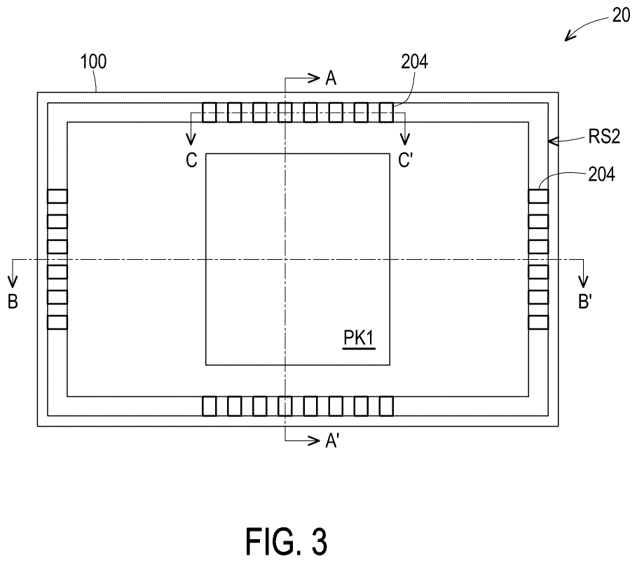

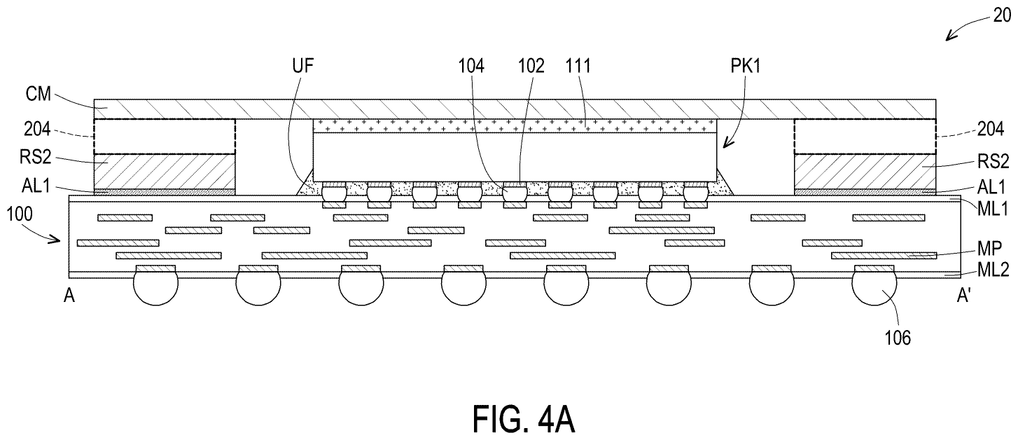

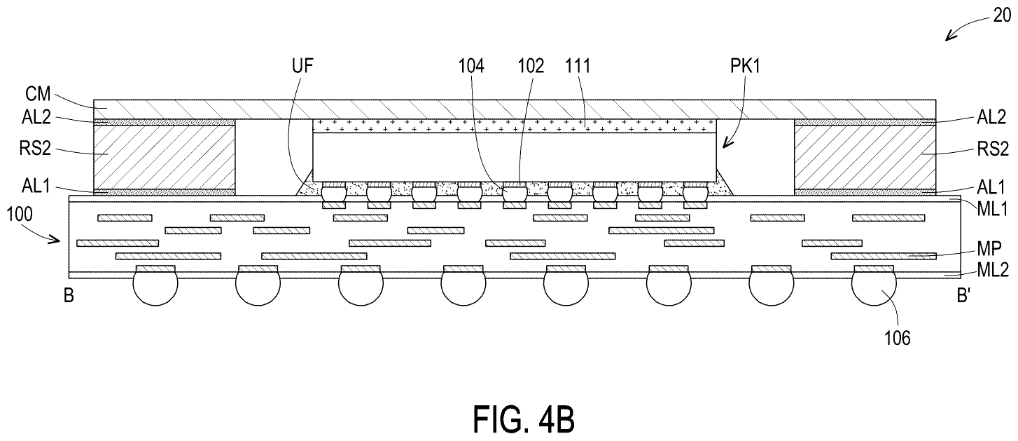

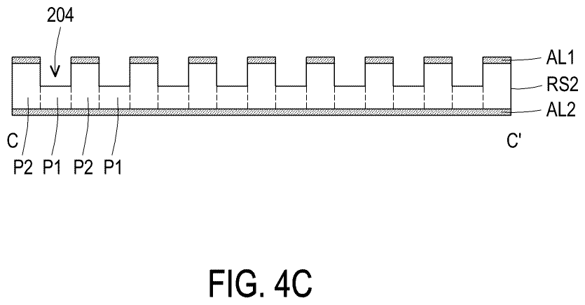

FIG. 3 is a simplified local top view of a semiconductor package in accordance with some embodiments. Through the specification, cavities denoted by a solid line indicate that the cavities are located in the upper part of the ring structure. FIG. 4A, FIG. 4B and FIG. 4C are schematic cross-sectional views of a semiconductor package taken along the lines A-A′, B-B′ and C-C′ of FIG. 3, respectively.

The element configuration and forming method of the semiconductor package 20 of FIG. 3, FIG. 4A, FIG. 4B and FIG. 4C are similar to the element configuration and forming method of the semiconductor package 10 of FIG. 1, FIG. 2A, FIG. 2B and FIG. 2C, so the difference is illustrated in details below, and the similarity is not iterated herein. One difference between the semiconductor package 20 and the semiconductor package 10 lies in the location of the ring cavities. In the semiconductor package 10, the cavities 202 are disposed in the lower part of the ring structure RS1. However, in the semiconductor package 20, the cavities 204 are disposed in the upper part of the ring structure RS2. Specifically, portions of the upper part of the ring structure RS2 are removed to form the cavities 204. From another point of view, the ring structure RS2 is patterned to have first portions P1 and second portions P2 alternatively, and the second portions P2 are thicker than the first portions P1. As shown in FIG. 4C, FIG. 4B and FIG. 4C, one of the cavities 204 is encompassed by one first portion P1 and two second portions P2, and the cavity 204 faces the overlying cover member CM. In some embodiments, the adhesive layer AL1 is a continuous adhesive layer between the ring structure RS2 and the underlying board substrate 100, and the adhesive layer AL2 is a discontinuous adhesive layer between the ring structure RS2 and the overlying cover member CM.

Another difference between the semiconductor package 20 and the semiconductor package 10 lies in the location of a passive device if any. In the semiconductor package 10, a semiconductor die PD such as a passive device is disposed in one of the cavities 202 of the ring structure RS1, and covered by or overlapped with the first portion P1 of the ring structure RS1. However, in the semiconductor package 20, a passive device (not shown) is disposed on the board substrate 100 and separated from the ring structure RS2, and may be located in an available space between the integrated circuit component PK1 and the ring structure RS2.

The above embodiments of FIG. 1, FIG. 2A, FIG. 2B and FIG. 2C in which the cavities 202 penetrate through the ring structure RS1 in a width direction thereof are provided for illustration purposes, and are not construed as limiting the present disclosure. In other embodiments, the cavities do not penetrate through the ring structure RS1 in a width direction thereof.

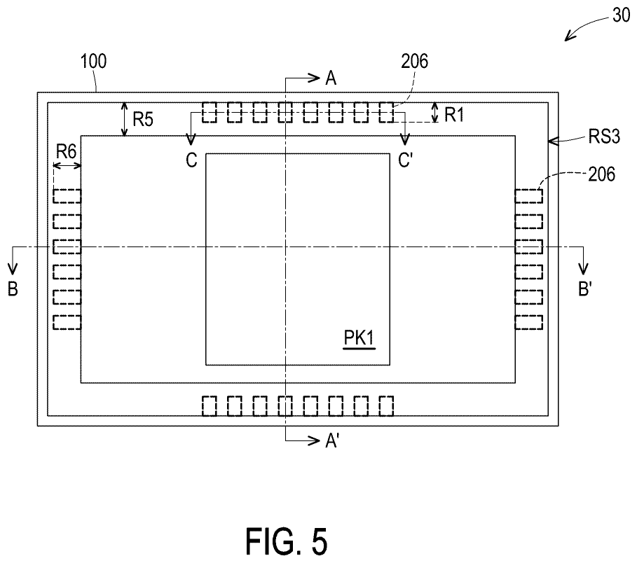

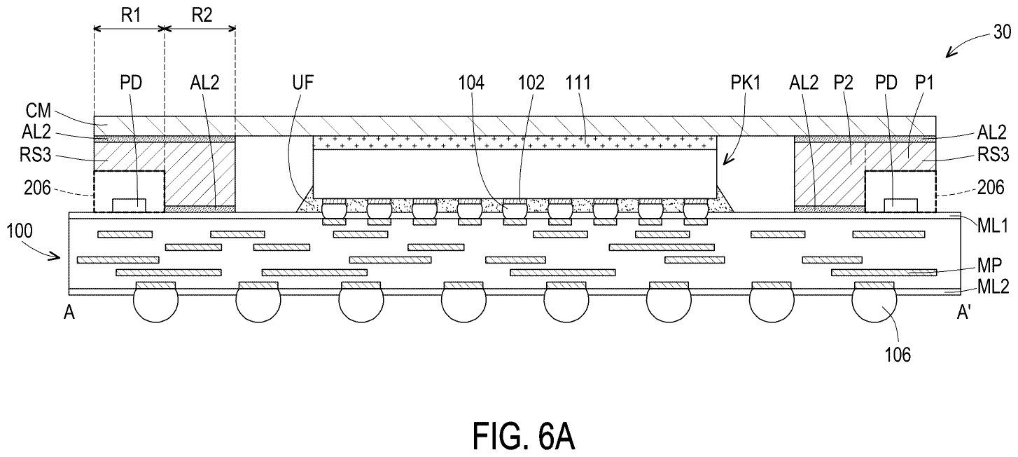

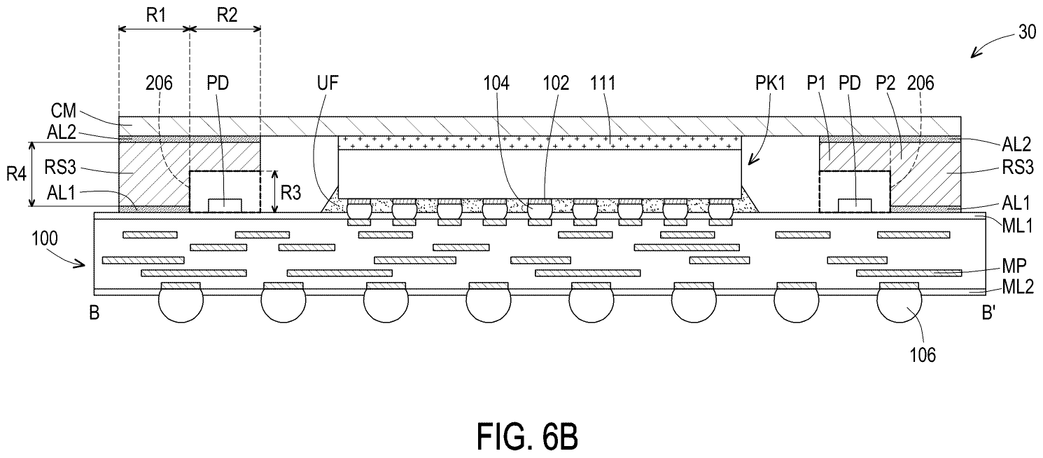

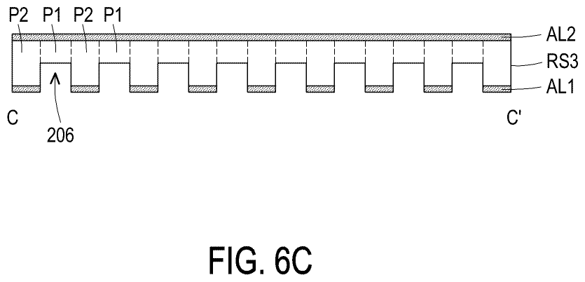

FIG. 5 is a simplified local top view of a semiconductor package in accordance with some embodiments. FIG. 6A, FIG. 6B and FIG. 6C are schematic cross-sectional views of a semiconductor package taken along the lines A-A′, B-B′ and C-C′ of FIG. 5, respectively.

The element configuration and forming method of the semiconductor package 30 of FIG. 5, FIG. 6A, FIG. 6B and FIG. 6C are similar to the element configuration and forming method of the semiconductor package 10 of FIG. 1, FIG. 2A, FIG. 2B and FIG. 2C, so the difference is illustrated in details below, and the similarity is not iterated herein. One difference between the semiconductor package 30 and the semiconductor package 10 lies in the top-view length of the cavities. In the semiconductor package 10, the top-view length of each cavity 202 is substantially the same as the ring width of the ring structure RS1. However, in the semiconductor package 30, the top-view length of each cavity 206 is different from (e.g. less than) the ring width of the ring structure RS3. From another point of view, the ring structure RS3 is patterned to have multiple first portions P1 and multiple second portions P2 thicker than the first portions P1, and three sides of each first portion P1 is surrounded by three second portions P2 arranged in a U-shape. The multiple first portions P1 are separated from one another, while the multiple second portions P2 are connected to each other. As shown in FIG. 6A, FIG. 6B and FIG. 6C, one of the cavities 206 is encompassed by one first portion P1 and three second portions P2, and the cavity 206 faces the underlying board substrate 100.

In some embodiments, as shown in FIG. 6A, the cavity length is denoted by R1, the distance from the cavity sidewall to the ring sidewall is denoted by R2, and the ratio of R1/R2 ranges from 0.1 to 3. In some embodiments, the ratio of R2/R1 is zero or greater. When the ratio of R2/R1 is zero, the cavities 206 penetrate through the ring structure RS3 in a width direction thereof, as shown in FIG. 1 and FIG. 2A. When the ratio of R2/R1 is greater than zero, the cavities 206 do not penetrate through the ring structure RS3 in a width direction thereof, as shown in FIG. 5 and FIG. 6A.

In some embodiments, as shown in FIG. 6B, the cavity depth is denoted by R3, the ring thickness is denoted by R4, and the ratio of R3/R4 ranges from 0.1 to 1. In some embodiments, as shown in FIG. 5, the cavity length is denoted by R6, the ring width is denoted by R5, and the ratio of R6/R5 ranges from 0.2 to 1. The cavity lengths R1 and R6 of the cavities 206 around the adjacent sidewalls of the integrated circuit component PK1 may be the same or different upon the design requirements.

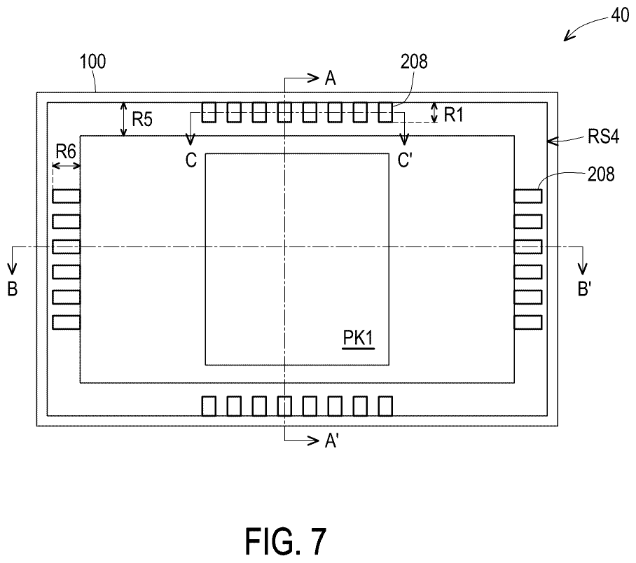

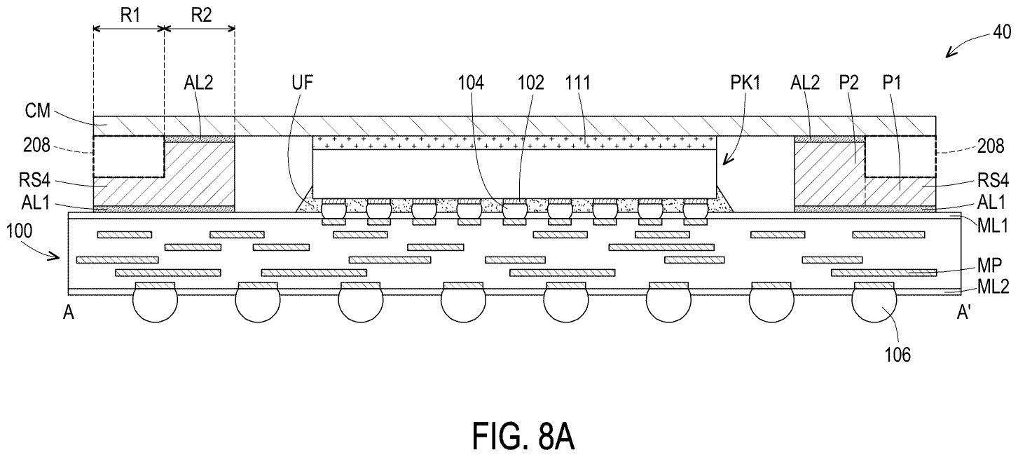

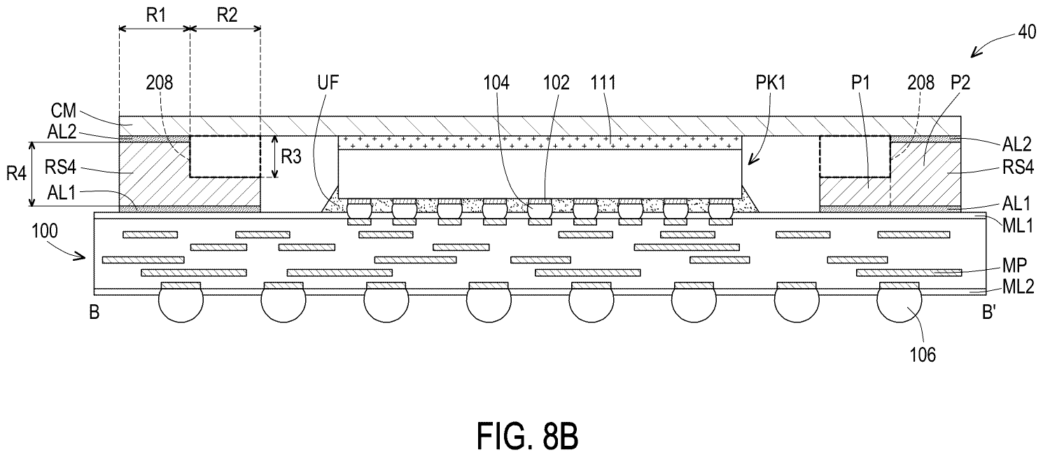

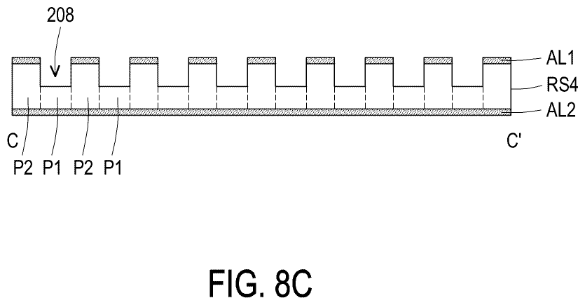

FIG. 7 is a simplified local top view of a semiconductor package in accordance with some embodiments. FIG. 8A, FIG. 8B and FIG. 8C are schematic cross-sectional views of a semiconductor package taken along the lines A-A′, B-B′ and C-C′ of FIG. 7, respectively.

The element configuration and forming method of the semiconductor package 40 of FIG. 7, FIG. 8A, FIG. 8B and FIG. 8C are similar to the element configuration and forming method of the semiconductor package 30 of FIG. 5, FIG. 6A, FIG. 6B and FIG. 6C, so the difference is illustrated in details below, and the similarity is not iterated herein. One difference between the semiconductor package 40 and the semiconductor package 30 lies in the location of the ring cavities. In the semiconductor package 30, the cavities 206 are disposed in the lower part of the ring structure RS3. However, in the semiconductor package 40, the cavities 208 are disposed in the upper part of the ring structure RS4. From another point of view, the ring structure RS4 is patterned to have multiple first portions P1 and multiple second portions P2 thicker than the first portions P1, and three sides of each first portion P1 is surrounded by three second portions P2 arranged in a U-shape. The multiple first portions P1 are separated from one another, while the multiple second portions P2 are connected to each other. As shown in FIG. 7A, FIG. 7B and FIG. 7C, one of the cavities 208 is encompassed by one first portion P1 and three second portions P2, and the cavity 208 faces the overlying cover member CM.

Another difference between the semiconductor package 40 and the semiconductor package 30 lies in the location of a passive device if any. In the semiconductor package 30, a semiconductor die PD such as a passive device is disposed in one of the cavities 206 of the ring structure RS3, covered by or overlapped with the first portion P1 of the ring structure RS3, and located aside the corresponding second portion P2 of the ring structure RS3. However, in the semiconductor package 40, a passive device (not shown) is disposed on the board substrate 100 and separated from the ring structure RS4, and may be located in an available space between the integrated circuit component PK1 and the ring structure RS4.

The above embodiments of FIG. 1 to FIG. 8C in which the longitude direction (or extending direction) of each of the cavities 202/204/206/208 is perpendicular to the corresponding sidewall of the integrated circuit component PK1 are provided for illustration purposes, and are not construed as limiting the present disclosure. In other embodiments, the longitude direction of each of the cavities is parallel to the corresponding sidewall of the integrated circuit component PK1. In other embodiments, the longitude direction of some cavities is perpendicular to the corresponding sidewall of the integrated circuit component PK1, while the longitude direction of some cavities is parallel to the corresponding sidewall of the integrated circuit component PK1.

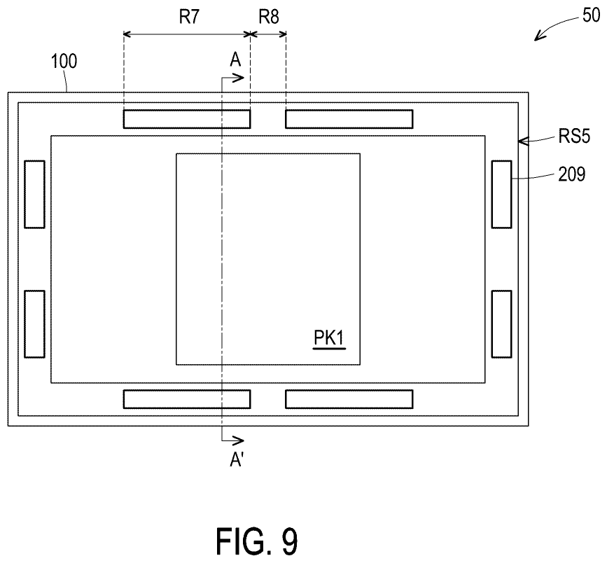

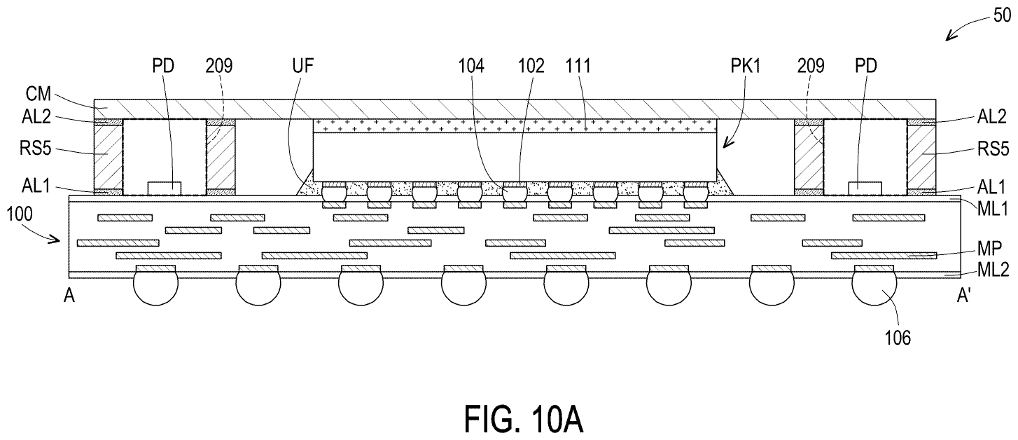

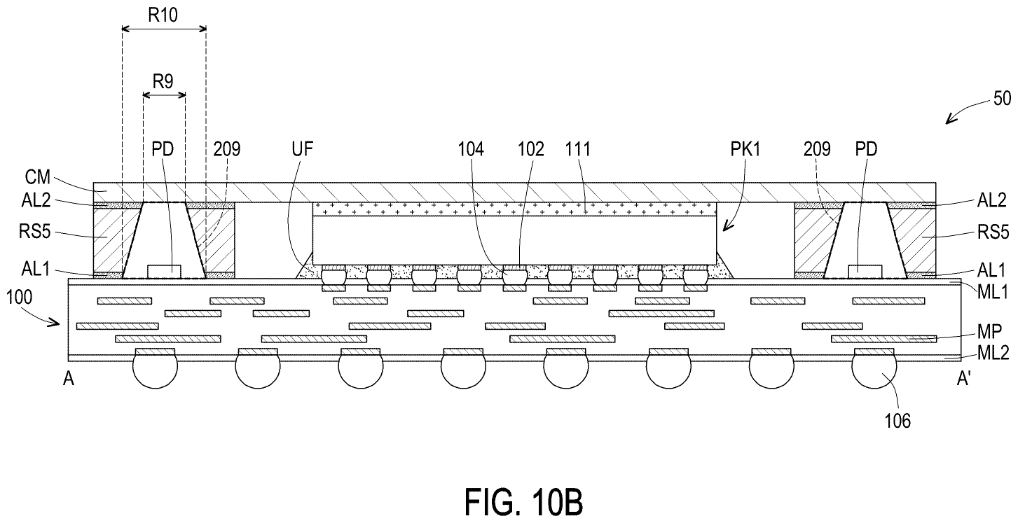

FIG. 9 is a simplified local top view of a semiconductor package in accordance with some embodiments. FIG. 10A and FIG. 10B are schematic cross-sectional views of semiconductor packages taken along the line A-A′ of FIG. 9, respectively.

The element configuration and forming method of the semiconductor package 50 of FIG. 9, FIG. 10A and FIG. 10B are similar to the element configuration and forming method of the semiconductor package 10 of FIG. 1 and, FIG. 2A, so the difference is illustrated in details below, and the similarity is not iterated herein. One difference between the semiconductor package 50 and the semiconductor package 10 lies in the longitude direction of the ring cavities. In the semiconductor package 10, the longitude direction of each of the cavities 202 of the ring structure RS1 is perpendicular to the corresponding sidewall of the integrated circuit component PK1. However, in the semiconductor package 50, the longitude direction of each of the cavities 209 of the ring structure RS5 is parallel to the corresponding sidewall of the integrated circuit component PK1. From another point of view, four sides of each cavity 109 is surrounded by the remaining portion of the ring structure RS5. In some embodiments, as shown in FIG. 9, the cavity length is denoted by R7, the cavity pitch is denoted by R8, and the ratio of R7/R8 ranges from 10 to 0.1.

As shown in FIG. FIG. 10A and FIG. 10B, the cavities 209 penetrate through the ring structure RS5 in a thickness direction thereof, and the cavities 209 exposes the underlying board substrate 100 and the overlying cover member CM. In some embodiments, each of the cavities 209 has substantially vertical sidewalls, as shown in FIG. 10A. In other embodiments, each of the cavities 209 has inclined sidewalls, as shown in FIG. 10B.

In some embodiments, the cavity top width is denoted by R9, the cavity bottom width is denoted by R10, and the ratio of R9/R10 ranges from 3 to 0.2. In some embodiments, when the ratio of R9/R10 is 1, each of the cavities 209 has substantially vertical sidewalls, as shown in FIG. 10A. In some embodiments, when the ratio of R9/R10 is less than 1, each of the cavities 209 has a trapezoid shape, as shown in FIG. 10B. In some embodiments, when the ratio of R9/R10 is greater than 1, each of the cavities 209 has an inverted trapezoid shape.

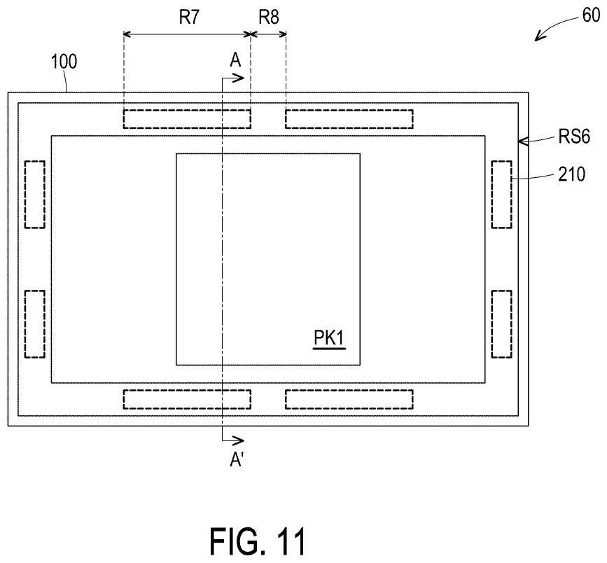

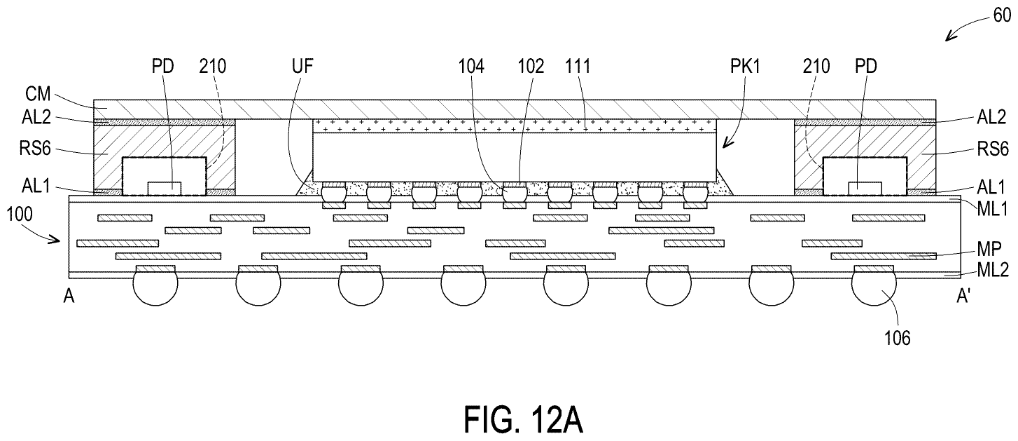

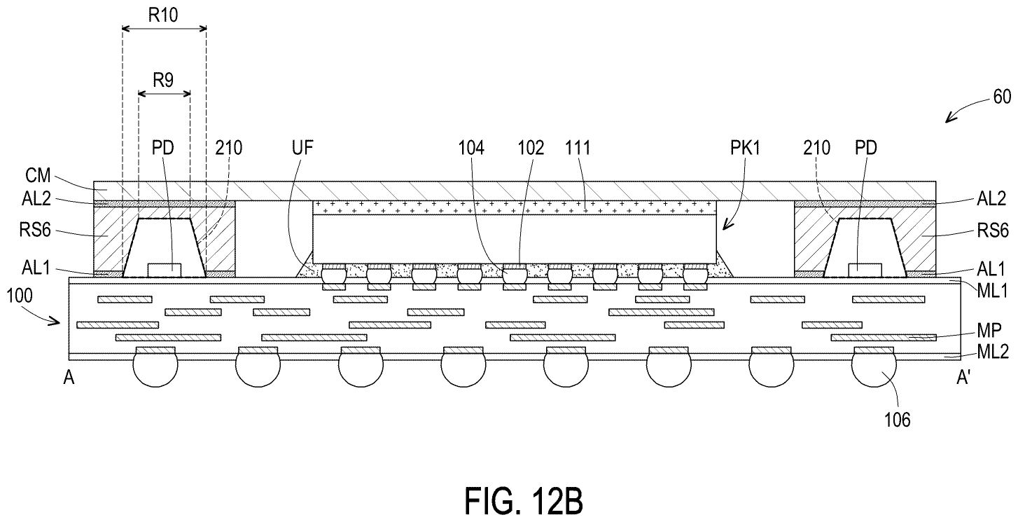

FIG. 11 is a simplified local top view of a semiconductor package in accordance with some embodiments. FIG. 12A and FIG. 12B are schematic cross-sectional views of semiconductor packages taken along the line A-A′ of FIG. 11, respectively.

The element configuration and forming method of the semiconductor package 60 of FIG. 11, FIG. 12A and FIG. 12B are similar to the element configuration and forming method of the semiconductor package 50 of FIG. 9, FIG. 10A and FIG. 10B, so the difference is illustrated in details below, and the similarity is not iterated herein. One difference between the semiconductor package 60 and the semiconductor package 50 lies in the depth of the ring cavities. In the semiconductor package 50, the cavities 209 penetrate through the ring structure RS5 in a thickness direction thereof, and the cavities 209 exposes the underlying board substrate 100 and the overlying cover member CM. However, in the semiconductor package 60, the cavities 210 do not penetrate through the ring structure RS6 in a thickness direction thereof, and the cavities 210 faces the underlying board substrate 100. In some embodiments, the cavities 210 do not penetrate through the ring structure RS6 in a thickness direction thereof, and the cavities 210 faces the overlying cover member CM.

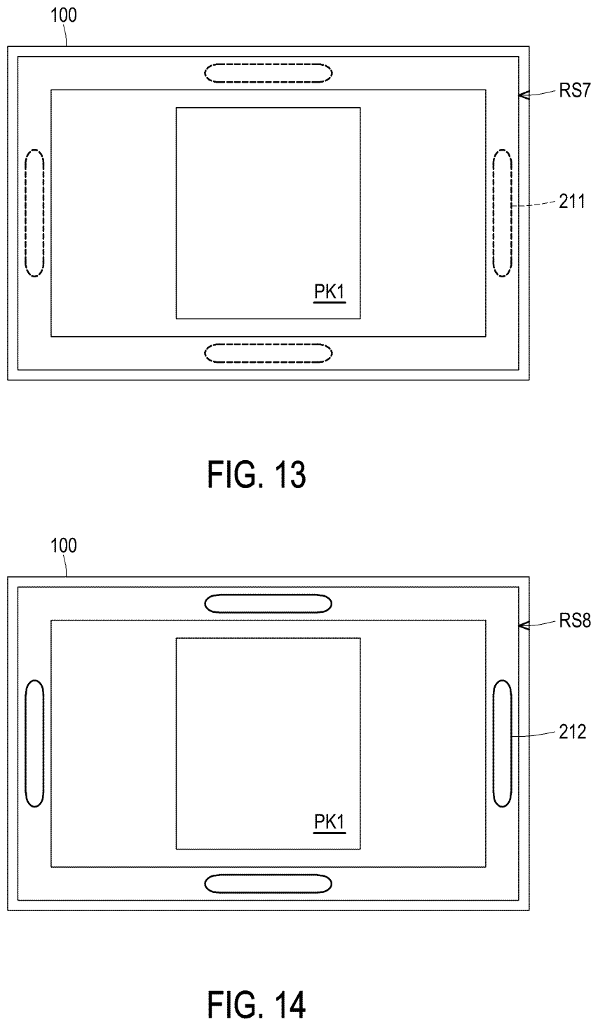

The above embodiments in which each of the cavities of the ring structure has a rectangular shape in a top view are provided for illustration purposes, and are not construed as limiting the present disclosure. In other embodiments, each of the cavities of the ring structure may have a bar-like shape with rounded opposite ends, as shown in FIG. 13 and FIG. 14.

The ring structure RS7 of FIG. 13 has cavities 211 located in the lower part of the ring structure RS7, and the cross-sectional views may refer to FIG. 12A and FIG. 12B. The ring structure RS8 of FIG. 14 has cavities 212 located in the upper part of the ring structure RS8.

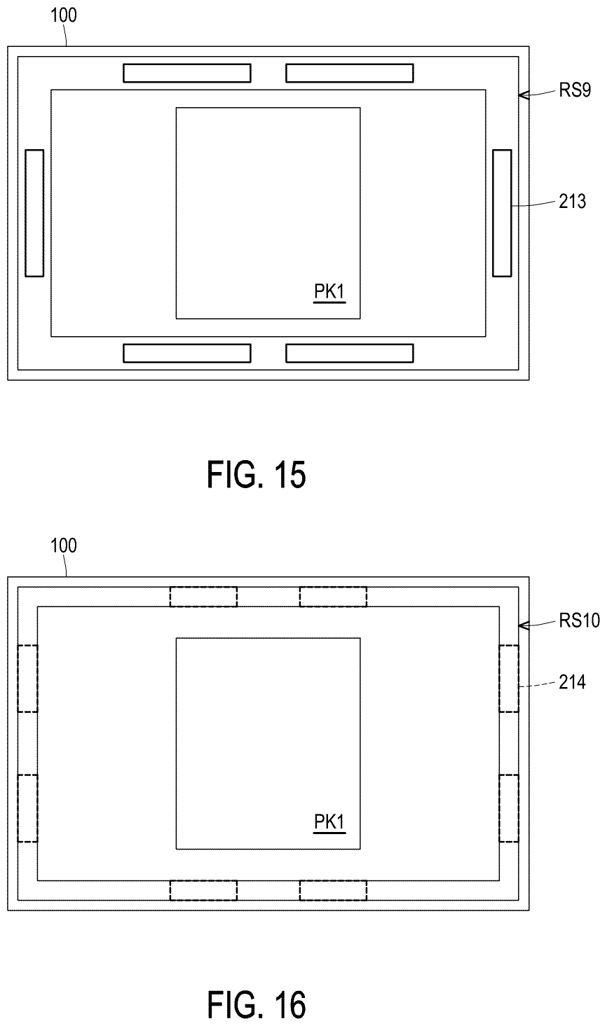

The ring structure RS9 of FIG. 15 is modified from the ring structure RS5 of FIG. 9. In FIG. 9, each sidewall of the integrated circuit component PK1 faces same number of cavities 209 (e.g., two cavities) of the ring structure RS5. In FIG. 15, the adjacent sidewalls of the integrated circuit component PK1 face different numbers of cavities 209 (e.g., one cavity and two cavities) of the ring structure RS9. The cross-sectional views may refer to FIG. 10A and FIG. 10B.

The ring structure RS10 of FIG. 16 is modified from the ring structure RS1 of FIG. 1. In FIG. 1, the longitude direction of each of the cavities 202 is perpendicular to the corresponding sidewall of the integrated circuit component PK1. In FIG. 16, the longitude direction of each of the cavities 214 is parallel to the corresponding sidewall of the integrated circuit component PK1. The cross-sectional views may refer to FIG. 2A and FIG. 2B.

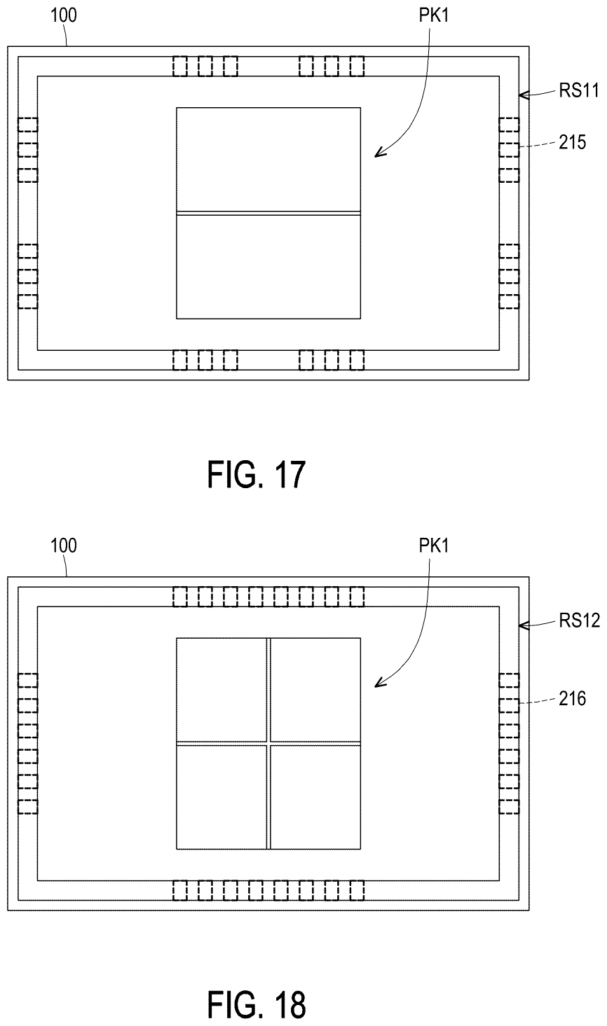

FIG. 17 to FIG. 21 are simplified local top views of semiconductor packages in accordance with some embodiments.

In the semiconductor package of FIG. 17, instead of one single semiconductor die or package structure discussed above, the integrated circuit component PK1 includes two semiconductor dies or two package structures laterally disposed. Besides, each sidewall of the integrated circuit component PK1 faces multiple cavities 215 of the ring structure RS11, and the cavities 215 are divided into two groups separated from each other by a distance greater than zero.

In the semiconductor package of FIG. 18, instead of one single semiconductor die or package structure discussed above, the integrated circuit component PK1 includes four semiconductor dies or four package structures arranged in an array. Besides, each sidewall of the integrated circuit component PK1 faces multiple cavities 216 of the ring structure RS12.

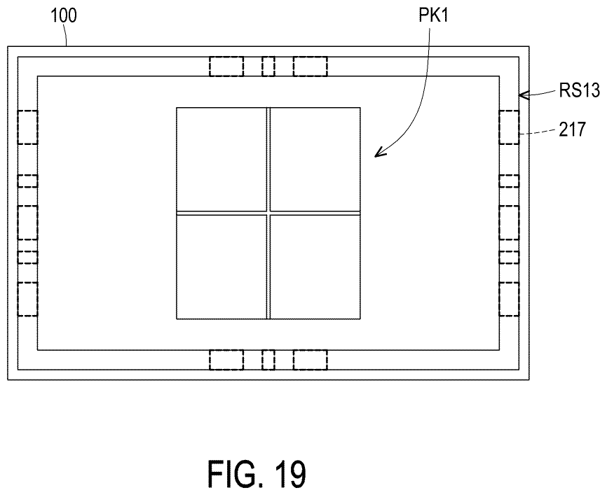

The semiconductor package of FIG. 19 is modified from the semiconductor package of FIG. 18. In the semiconductor package of FIG. 18, the cavities 216 of the ring structure RS12 have substantially the same size and are distributed uniformly in a region facing the corresponding sidewall of the integrated circuit component PK1. In the semiconductor package of FIG. 19, the cavities 217 of the ring structure RS13 have different sizes and are distributed along the periphery of the integrated circuit component PK1. Specifically, the cavities 217 of the ring structure RS13 have narrow portions and wide portions alternatively arranged, and two adjacent sidewalls of the integrated circuit component PK1 face different numbers of the narrow portions and wide portions.

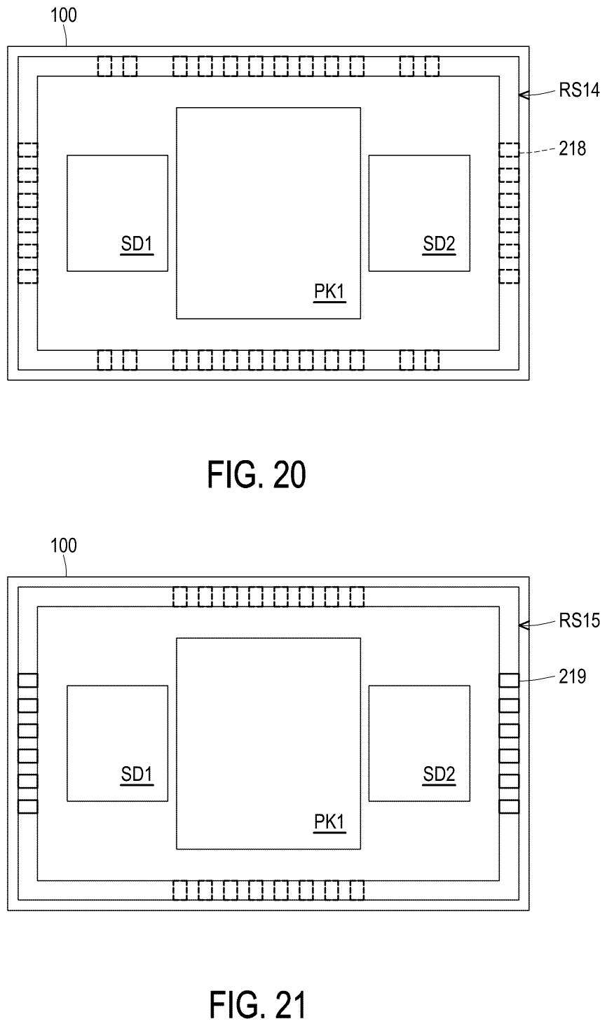

In the semiconductor package of FIG. 20, other than one single semiconductor die or package structure discussed above, additional semiconductor dies SD1 and SD2 are further included and mounted on the board substrate. In some embodiments, the additional semiconductor dies SD1 and SD2 may be passive devices such as capacitors, resistors, inductors, varactors, and/or similar components. In some embodiments, at least one of the additional semiconductor dies SD1 and SD2 may be a silicon dummy die. Besides, the cavities 218 of the ring structure RS14 are not uniformly distributed. Specifically, cavities 218 are not disposed in some regions subjected to less lid expansion/bending.

The semiconductor package of FIG. 21 is modified from the semiconductor package of FIG. 20. In the semiconductor package of FIG. 20, all of the cavities 218 are located in the lower part of the ring structure RS14 and face the underlying board substrate. In the semiconductor package of FIG. 21, some of the cavities 219 are located in the lower part of the ring structure RS15 and face the underlying board substrate, and the cross-sectional views may refer to FIG. 2A and FIG. 2B. In the semiconductor package of FIG. 21, some of the cavities 219 are located in the upper part of the ring structure RS15 and face the overlying cover member, and the cross-sectional views may refer to FIG. 4A and FIG. 4B.

The above embodiments in which the ring structures have cavities with specific shapes and configurations are provided for illustration purposes, and are not to be construed as limiting the scope of the present disclosure. In other words, the shapes, sizes, variations, configurations and distributions of the cavities of the ring structure are not limited by the present disclosure. A ring structure with cavities is contemplated as falling within the spirit and scope of the present disclosure as long as such ring structure is beneficial to reduce the ring stiffness and therefore mitigate the bending force from the expansion of the ring structure and the overlying lid.

The structures of the semiconductor packages of the disclosure are described below with reference to FIG. 1 to FIG. 21.

In some embodiments, a semiconductor package includes a board substrate 100, an integrated circuit component PK1 and a ring structure (e.g., RS1-RS15). The integrated circuit component PK1 is bonded to the board substrate 100 and includes at least one semiconductor die. The ring structure is disposed on the board substrate 100 and encircles the integrated circuit component PK1, wherein the ring structure includes a plurality of cavities (e.g., 202-219) around a boundary of the integrated circuit component PK1.

In some embodiments, the cavities (e.g., 209) penetrate through the ring structure. In some embodiments, the cavities (e.g., 202, 204, 206, 208, 210-219) do not penetrate through the ring structure.

In some embodiments, the cavities (e.g., 202, 206, etc.) face the board substrate 100. In some embodiments, the cavities (e.g., 204, 208, etc.) face away from the board substrate 100. In some embodiments, some of the cavities (e.g., 219) face the board substrate 100, and some of the cavities (e.g., 219) face away from the board substrate 100.

In some embodiments, a longitude direction of the cavities (e.g., 202, 204, 206, 208, 215-219) is perpendicular to a corresponding sidewall of the integrated circuit component PK1. In some embodiments, a longitude direction of the cavities (e.g., 209, 210-214) is parallel to a corresponding sidewall of the integrated circuit component PK1.

In some embodiments, a cover member CM is further included and disposed on the ring structure and the integrated circuit component.

In some embodiments, a semiconductor package includes a board substrate 100, an integrated circuit component PK1, a ring structure (e.g., RS1-RS15) and a cover member CM. The integrated circuit component PK1 is bonded to the board substrate and includes at least one semiconductor die. The ring structure is disposed on the board substrate and encircles the integrated circuit component PK1. The ring structure includes first portions P1 and second portions P2 thicker than the first portions. The cover member is disposed on the ring structure and the integrated circuit component.

In some embodiments, the first portions P1 of the ring structure (e.g., RS1, RS3, etc.) are in contact with the cover member CM.

In some embodiments, the first portions P1 of the ring structure (e.g., RS2, RS4, etc.) are separated from the cover member CM.

In some embodiments, the second portions P2 of the ring structure (e.g., RS5, RS6) have inclined sidewalls.

In some embodiments, the second portions P2 of the ring structure (e.g., RS5, RS6) have substantially vertical sidewalls.

In some embodiments, a passive device PD is disposed on the board substrate 100 corresponding to one of the first portions P1 of the ring structure (e.g., RS1, RS3, etc.).

In some embodiments, a discontinuous adhesive layer AL1 between the ring structure (e.g., RS1, RS3, etc.) and the board substrate 100. In some embodiments, a discontinuous adhesive layer AL2 between the ring structure (e.g., RS2, RS4, etc.) and the cover member CM.

In view of above, in the disclosure, in a semiconductor package of the disclosure, a ring structure with cavities is mounted on a board substrate and surrounds an integrated circuit component, so as to reduce the ring stiffness and therefore mitigate the bending force from the expansion of the ring structure and the overlying lid to the board substrate during the high-temperature (HT) process. The ring structure of the disclosure is provided with cavities at middle sections thereof (rather than at corners thereof), and thus, the coupling bending/expansion effect between the lid and the ring during the high-temperature (HT) process is reduced while adhesive delamination between the lid and the ring is avoided. Accordingly, the package reliability is accordingly enhanced.

Many variations of the above examples are contemplated by the disclosure. It is understood that different embodiments may have different advantages, and that no particular advantage is necessarily required of all embodiments.

In accordance with some embodiments of the present disclosure, a semiconductor package includes a board substrate, an integrated circuit component and a ring structure. The integrated circuit component is bonded to the board substrate and includes at least one semiconductor die. The ring structure is disposed on the board substrate and encircles the integrated circuit component, wherein the ring structure includes a plurality of cavities around a boundary of the integrated circuit component.

In accordance with some embodiments of the present disclosure, a semiconductor package includes a board substrate, an integrated circuit component, a ring structure and a cover member. The integrated circuit component is bonded to the board substrate and includes at least one semiconductor die. The ring structure is disposed on the board substrate and encircles the integrated circuit component. The ring structure includes first portions and second portions thicker than the first portions. The cover member is disposed on the ring structure and the integrated circuit component.

In accordance with some embodiments of the present disclosure, a method of forming a semiconductor package includes following operations. An integrated circuit component is bonded to a board substrate, and the integrated circuit component includes at least one semiconductor die. An underfill layer is formed between the integrated circuit component and the board substrate. A ring structure is attached to the board substrate, wherein the ring structure encircles the integrated circuit component, and includes a plurality of cavities around a boundary of the integrated circuit component.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising;
a board substrate;
an integrated circuit component, bonded to the board substrate and comprising at least one semiconductor die; and
a ring structure, disposed on the board substrate and encircling the integrated circuit component, wherein the ring structure comprises a plurality of cavities around a boundary of the integrated circuit component.

2. The semiconductor package of claim 1, wherein the cavities penetrate through the ring structure.

3. The semiconductor package of claim 1, wherein the cavities do not penetrate through the ring structure.

4. The semiconductor package of claim 1, wherein the cavities face the board substrate.

5. The semiconductor package of claim 1, wherein the cavities face away from the board substrate.

6. The semiconductor package of claim 1, wherein some of the cavities face the board substrate, and some of the cavities face away from the board substrate.
The semiconductor package of claim 1, wherein a longitude direction of the cavities is perpendicular to a corresponding sidewall of the integrated circuit component.

8. The semiconductor package of claim 1, wherein a longitude direction of the cavities is parallel to a corresponding sidewall of the integrated circuit component.

9. The semiconductor package of claim 1, further comprising a cover member disposed on the ring structure and the integrated circuit component.

10. A semiconductor package, comprising;
a board substrate;
an integrated circuit component, bonded to the board substrate and comprising at least one semiconductor die;
a ring structure, disposed on the board substrate and encircling the integrated circuit component, wherein the ring structure comprises first portions and second portions thicker than the first portions; and
a cover member, disposed on the ring structure and the integrated circuit component.

11. The semiconductor package of claim 10, wherein the first portions are in contact with the cover member.

12. The semiconductor package of claim 10, wherein the first portions are separated from the cover member.

13. The semiconductor package of claim 10, wherein the second portions have inclined sidewalls.

14. The semiconductor package of claim 10, wherein the second portions have substantially vertical sidewalls.

15. The semiconductor package of claim 10, further comprising a passive device disposed on the board substrate corresponding to one of the first portions.

16. The semiconductor package of claim 10, further comprising a discontinuous adhesive layer between the ring structure and the board substrate.

17. A method of forming a semiconductor package, comprising:
bonding an integrated circuit component to a board substrate, wherein the integrated circuit component comprises at least one semiconductor die;
forming an underfill layer between the integrated circuit component and the board substrate; and
attaching a ring structure to the board substrate, wherein the ring structure encircles the integrated circuit component, and comprises a plurality of cavities around a boundary of the integrated circuit component.

18. The method of claim 17, further comprising bonding a passive device to the board substrate before attach the ring structure to the board substrate, wherein the passive device corresponds to one of the cavities.

19. The method of claim 17, wherein the cavities penetrating through the ring structure.

20. The method of claim 17, wherein the cavities do not penetrate through the ring structure.
